(19) United States
(12) Patent Application Publication
(10) Pub. No.: US 2010/0046152 A1
(43) Pub. Date: Feb. 25, 2010

(54) Mobile airline check-in counter with integrated baggage scale

(76) Inventors: Walid Fouad Ghobrial, Sanford, NC (US); Talaat Magdy Iskander, Oshawa (CA)

Correspondence Address: DAVID MILOSEVIC, 185 Carlton, Toronto, ON, MSA2K7, CA

(21) Appl. No.: 12/154,817

(22) Filed: Aug. 21, 2008

(51) Int. Cl. H05K 5/02

(52) U.S. Cl. 361/679.4

(57) ABSTRACT

One embodiment of a mobile airline check-in counter with integrated baggage scale wherein the mobile unit contains a plurality of shelves to house supplies and equipment associated with the airline baggage check-in process and including an integrated and retractable baggage scale mounted on a caster system. Other embodiments are described.

### CROSS REFERENCE TO RELATED APPLICATIONS

None

### FEDERALLY SPONSORED RESEARCH

Not applicable

### BACKGROUND OF THE INVENTION

1. Field of the Invention

This invention generally relates to mobile counters and more particularly to a mobile airline check-in counter designed to provide mobile check-in services and baggage weighing at airports in order to make possible the speedier weighing and checking-in of airline baggage. The mobile check-in unit can be easily moved to supplement the scales available at a fixed airline check-in counter, or can be positioned at suitable locations throughout an airport to provide check-in services as needed to meet passenger check-in needs.

2. Prior Art

It is standard practice throughout the airline industry that an airline passenger with baggage to be checked for loading on the aircraft will deposit baggage on a scale platform built into a check-in counter. The attendant at the counter reads the weight of the checked-in baggage to determine that it does not exceed maximum weight allowances for checked-in baggage that have been established by the airline. Normally, a surcharge applies to every additional pound that the checked-in baggage exceeds the maximum allowable baggage weight included within the price of each airline ticket. After weighing the baggage, the attendant will tag the luggage to its appropriate destination and issue a boarding pass to the passenger.

Waiting times at airline check-in counters can often be significant, leading to frustration among passengers and airline staff, as well as potential delays and missed flights. Unfortunately, even with additional staff on hand to assist with checking-in of passengers, there are only a fixed number of baggage processing stations to weigh and tag passenger baggage, thus creating a bottleneck in the airlines' ability to quickly check-in their passengers.

Those concerned with these and related problems with airline check-in recognize the need for an improved system to speed up baggage processing at the airline counter check-in.

### SUMMARY

The present invention discloses a mobile airline check-in counter with integrated baggage scale that houses a computer terminal, printer for issuing boarding passes as well as a baggage scale, thereby allowing checking-in of passengers to be accomplished at any convenient location throughout an airport. The mobile check-in unit is constructed of stainless steel and is therefore durable and long lasting. The wheels on the unit make it easy to manipulate by check-in counter attendants. A retractable baggage scale is provided at the bottom of the unit. The baggage scale is attached to a retractable scale tray assembly, allowing the scale to be easily stored within the unit when the unit is being moved.

The retractable scale tray assembly includes folding caster wheels that extend when the assembly is withdrawn from its housing, thereby providing support to the entire scale assembly, without compromising mobility. The retractable scale tray assembly is designed for withdrawal from both the left and right hand sides of the unit, thereby allowing flexibility in positioning the unit next to walls or in areas where space is limited.

The mobile check-in counter is designed to overcome the disadvantages of the present airline check-in counter workplace related to the weighing and rapid processing of passenger baggage. The mobile check-in counter can be quickly and easily positioned to provide supplemental baggage processing during peak check-in times, or can be positioned in any convenient area in the airport to provide flexibility in check-in locations. The advantages offered by the mobile check-in unit will result in shorter check-in times and less stress and aggravation for passengers and airline staff. The mobile check-in units can be expected to facilitate airline check-in procedures thereby providing higher levels of customer satisfaction and an overall improvement in the air travel experience.

### BRIEF DESCRIPTION OF THE SEVERAL VIEWS OF THE DRAWINGS

Other objects, advantages, and novel features of the present invention will become apparent from the following detailed description of the invention when considered in conjunction with the accompanying drawings, wherein:

FIG. 1 is a side elevational view of the mobile airline check-in counter with integrated baggage scale showing the rear of the unit that will face the airline counter employee, the top, and right hand side and the right hand side door of the unit;

FIG. 2 is a side elevational view showing the front (outside face) of the unit, a rear facing view of the top of the unit and its handle, as well as the right hand side and right hand side door of the unit;

FIG. 3 is a view of the unit in the position described in FIG. 1 with the facing of the unit removed to show the interior shelves and trays of the unit.

### DETAILED DESCRIPTION OF THE PREFERRED EMBODIMENT

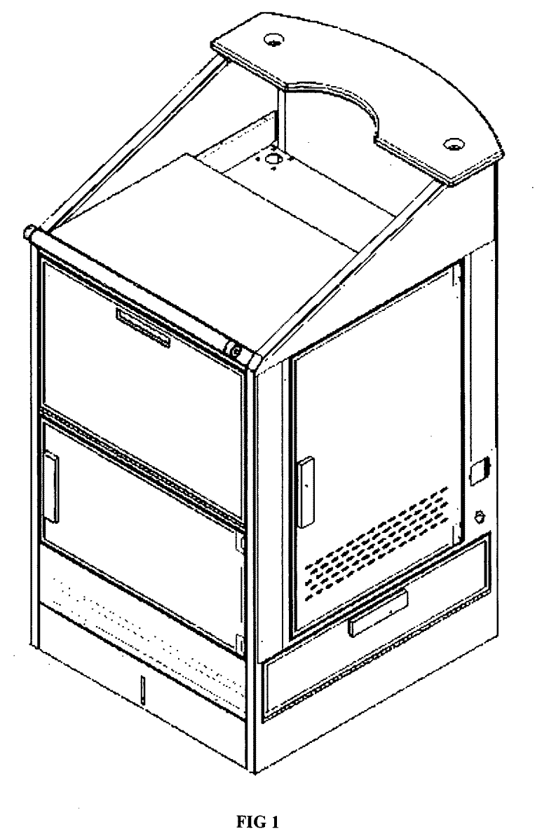

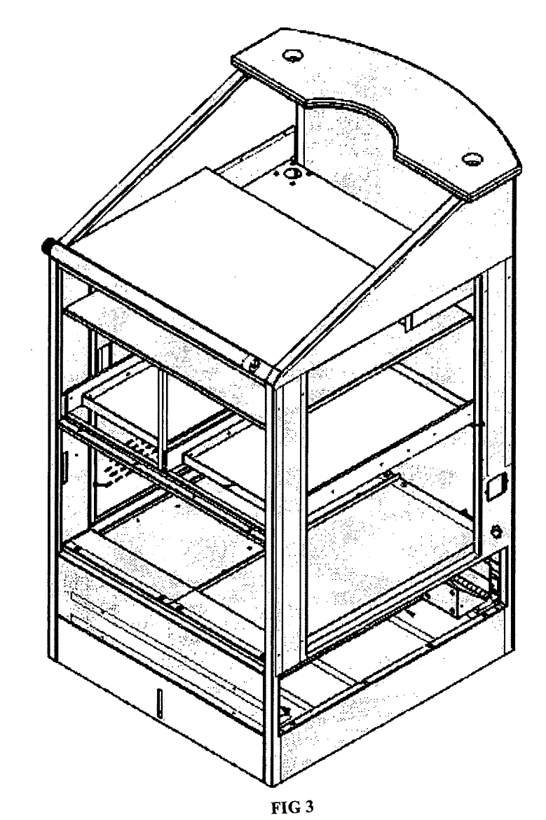

Referring now specifically to the drawings and the illustrated embodiments depicted therein, a mobile airline check-in counter with integrated baggage scale is shown in FIGS. 1, 2, and 3. The mobile counter comprises a box-like unit defining a hollow interior FIG. 3. The entire unit is mounted on caster wheels affixed to the bottom of the unit (not shown) to provide mobility to the unit.

The mobile unit includes rear access doors 9 and 24, a front door 3, a left hand door 7 and a right hand door 5. The left and right hand doors 5 and 7 are perforated to allow cooling of the interior of the unit. Doors are rigidly interconnected to form a stable structure and can be made of any number of materials, although stainless steel may be the preferred material based on projected wear and tear.

The rear access doors 9 and 24 allow easy access to the internal top shelf 29, which can be used for storage of a computer and of supplies required for check-in staff, perforated printer trays 25 and 27 which support the printer (not shown) for printing of tags and boarding passes, and perforated battery trays 10 and 11 supporting the rechargeable battery packs (not shown) to provide auxiliary power to the unit. The right hand side door 5 provides access to the shelf 29 and trays 10, 11, 25 and 27. The bottom right hand side door 6 folds upwards to provides access to the retraceable scale tray assembly 14 which supports the baggage scale (not shown) to weigh passenger baggage.

The top of the unit 33 is specifically adapted to receive different types of computer keyboards and amenity trays that will allow the unit to be adapted for different uses and also to customize the unit for various airlines' requirements. Guide holes (shown but not numbered) are provided for computer cables and wiring in the top of the unit to allow computer wires to be concealed within the unit and attached to the power supply within the unit. Extrusion points for the egress of printed materials are supplied in the top of the unit (not shown).

The rear top of the unit includes a steering bar 20 affixed along the width of the unit to allow for easy maneuverability of the unit. The top of the unit includes a privacy barrier 32 to prevent access to materials held on top of the unit and to provide a platform to which notices, signs or advertising may be affixed. It is expected that the privacy barrier 32 will be adapted to incorporate a digital readout from the integrated baggage scale housed in the mobile check-in unit.

As mentioned, a computer and supply shelf 29 is included inside the unit. The shelf is easily accessible through an access door 24 at the rear of the unit. The access door 24 includes a lock assembly (not shown) and can be designed to open on a hinge that allows the door to be opened upward, to the bottom, or to the left or the right. Alternatively, the access door 24 can be designed to retract into the unit. The shelf 29 is designed to provide a storage area for a computer, paperwork, printing supplies, or other material required for the check-in process. The interior of the unit also includes two perforated printer trays 25 and 27 supported on a structurally enhanced support system affixed to the interior walls of the unit 26. The availability of two printer trays allows flexibility and simultaneous printing of baggage claim stubs boarding passes or other material that may be in various formats. The unit includes two perforated battery trays 10 and 11 which support rechargeable battery packs used to power the various components housed within the unit. Both the printer trays 25 and 27 and the battery trays 10 and 11 are perforated to allow air circulation and cooling within the unit. As mentioned, the top shelf 29 and the printer trays 25 and 27 can be accessed through the top rear access door 24. The battery trays 10 and 11 are accessible through the bottom rear access door 9. The entire inside of the unit is also accessible through the right hand door 5. The shelf 29 and trays 10, 11, 25 and 27 within the unit can be adjusted to different heights depending on use requirements.

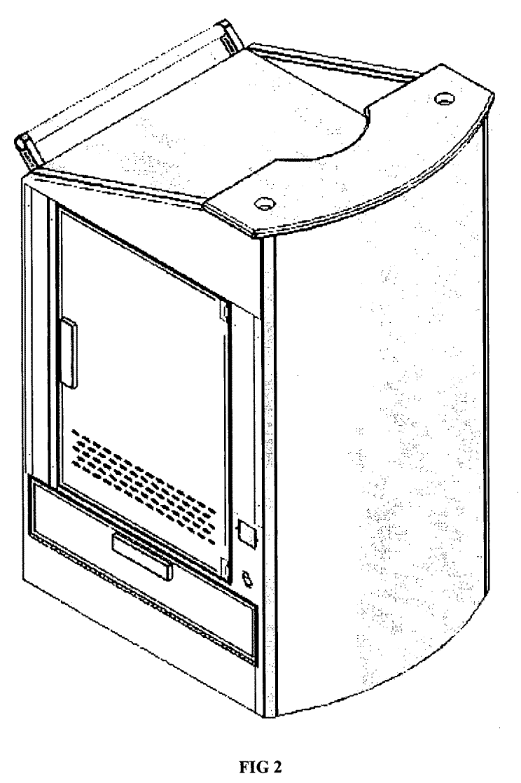

The baggage scale (not shown) is affixed to a baggage scale tray assembly 14 located at the bottom of the unit. As mentioned, the baggage scale tray assembly 14 is located behind a baggage tray assembly door 6 which can be designed to open upwards, downward or to retract within the unit. The baggage tray assembly door 6 is fitted with a lock assembly 22 which can be included at any position on the baggage tray assembly door 6 but is shown in the center of the baggage tray assembly door 6 in FIG. 1 and FIG. 2.

The baggage tray assembly 14 is mounted on a supporting slider 12 and 13 on its left and right hand sides, allowing the entire baggage tray assembly 14 to be easily withdrawn from the unit through the baggage tray assembly door 6. The proposed embodiment includes a baggage tray assembly door on the right hand side of the unit 6 as well as on the left hand side of the unit (not shown) to allow the baggage tray assembly 14 to be withdrawn from either side of the unit. A collapsible caster wheel assembly is affixed to the front, lengthwise edge of the baggage tray assembly 18, allowing the caster assembly to automatically protract when the baggage tray assembly 14 is withdrawn from the unit, thus providing support to the baggage tray assembly 14 as well as continued mobility of the entire unit. A locking system can be included on the caster wheel assembly to prevent accidental movement of the unit while it is in use. When the baggage tray assembly 14 is stored back inside the unit, the retractable castor wheel assembly is designed to automatically fold upward allowing the baggage tray assembly to be easily withdrawn into the unit.

### Operation—First Embodyment—Figs

The manner of using the Mobile Airline Check-in Counter with Integrated Baggage Scale is straightforward. Airline check-in staff can position the unit next to a fixed airline check-in location to provide supplemental check-in services, or the unit can be positioned at various locations in the airport where check-in services are required. The unit provides airline check-in staff with all of the tools required to quickly process passenger baggage. The integrated baggage scale (not shown) occupies a retractable scale assembly 14 located near the bottom of the unit. The retractable scale assembly 14 can be withdrawn from either the right or left side of the unit, allowing for use of the unit next to obstacles or narrow spaces. The interior top shelf of the unit 29 provides storage space for a computer, printing material, baggage tags, and other supplies required for the check-in process. The printer trays 25 and 27 provide support for printers (not shown) that are used to print baggage tags or boarding passes. Printer output can be routed to the top of the unit for egress through specially designed extrusion points. The battery tray 10 provides support for rechargeable battery packs (not shown) that will be used to provide auxiliary power for the devices contained in the unit, including the electronic scale, printers, and any computer equipment. Access to the internal shelves 10, 11, 25, 27, and 29 is provided through rear doors 9 and 24, and the side door 5. Once the unit is positioned where required, the retractable scale is withdrawn from its housing through a folding housing [continued on next page] door 6 which is hinged to fold upwards. The baggage scale rests on a panel scale tray assembly 14 which is affixed to support sliders 12 and 13 on the inside of the unit allowing the entire scale tray assembly to be withdrawn from the unit through either the right hand side scale tray assembly door 6 or the left hand scale tray assembly door (not shown). The scale tray assembly 14 includes a folding caster wheel assembly 18 which allows the caster wheels (not shown) that support the extended scale tray assembly to fold up and under the scale tray assembly 14 when the scale tray assembly 14 is retracted into the unit.

The weight of the baggage placed on the scale is displayed on a digital display that can be mounted in the privacy barrier 32. Following weighing and tagging of baggage, the baggage is forwarded to baggage handling staff for loading onto the aircraft.

### Conclusions, Ramifications, and Scope

Accordingly, the reader will see that, according to one embodiment of the invention that has been provided, the mobile unit contains a number of internal shelves and trays to house a computer, supplies, printers, batteries and a retraceable baggage scale. The mobile check-in unit is designed to be constructed of stainless steel. While the above description contains a number of specifications, these should not be construed as limitations on the scope of any embodiment, but as exemplifications of the presently preferred embodiments thereof. Many other ramifications and variations are possible within the teachings of the various embodiments.

For example, the unit can be configured to house various specific check-in equipment that airlines may decide to implement, including scanners of various types, security equipment or various computer equipment designed to increase the efficiency of the baggage check-in process. Thus the scope of the invention should be determined by the appended claims and their legal equivalents, and not by the examples given.

I claim:

1. A mobile airline check-in counter, and the like, comprising:
a. a stainless steel or steel cabinet mounted on a wheeled caster system having a rigid exterior and hollow interior shaped to receive and house components and materials related to airline passenger check-in services, with an integrated and retractable baggage scale assembly constituting an integral part thereof.
b. a shelf mounted in the inside of the said mobile airline check-in counter, affixed to the interior of the unit and allowing for adjustable height thereof;
c. perforated trays for printers and battery power supplies mounted inside the interior of the unit and allowing for adjustable height thereof;
d. a top providing for the placement of work trays, or computers, with guide holes for threading of cables and electrical wires to connect to the internal power supply and egress points allowing for extrusion of printed materials;
e. a retractable scale tray assembly to which is affixed a baggage scale of the type normally used at airline check-in counters whereby said retractable scale tray assembly can be extended from within the unit, through a right or left hand access door and where said retractable scale tray assembly is fitted with retractable caster wheels which provide support to the retractable scale tray assembly.
f. a plurality of access doors on the rear and sides of the mobile airline check-in counter that are provided with locking mechanisms and which allow for access to the various shelves, and trays housed within the unit;
g. a power supply consisting of battery power packs to allow the mobile unit to be used away from an external power source, as well as a wall source power connection for use with standard power outlets.

2. The mobile airline check-in counter as defined in claim 1 wherein said internal trays for supporting printers and battery power supplies are supplemented or replaced by additional or replacement trays for supporting a plurality of various types of equipment that may be required in the airline check-in process.

3. The mobile airline check-in counter as defined in claim 1 having a top wherein a digital display is mounted into the top or front face of the mobile unit providing a display of the baggage weighed by the integrated baggage scale.

4. The mobile airline check-in counter as defined in claim 1 constructed of a plurality of materials including suitably durable plastics, aluminum, steel, glass, and any combination thereof.

5. The mobile airline check-in counter as defined in claim 1 adapted for use in train station, bus stations, ferries, and passenger ships.
